(19) United States
(12) Patent Application Publication
(10) Pub. No.: US 2018/0364527 A1
(43) Pub. Date: Dec. 20, 2018

(54) ARRAY SUBSTRATE AND METHOD FOR MANUFACTURING THE SAME AND LIQUID CRYSTAL DISPLAY PANEL

(71) Applicant: Shenzhen China Star Optoelectronics Semiconductor Display Technology Co., Ltd., Shenzhen (CN)

(72) Inventor: Zhuming DENG, Shenzhen (CN)

(21) Appl. No.: 15/571,049

(22) PCT Filed: Aug. 14, 2017
(86) PCT No.: PCT/CN2017/097319

§ 371 Date: Nov. 1, 2017

(30) Foreign Application Priority Data
Jun. 20, 2017 (CN) 201710468319.0

(51) Int. Cl. G02F 1/1343; H01L 27/12; G02F 1/1335; G02F 1/1368

(52) U.S. Cl. CPC G02F 1/134309; H01L 27/1222; G02F 2201/123; G02F 1/133514; G02F 1/1368; H01L 27/1259

(57) ABSTRACT

An array substrate and a method for manufacturing the same and a liquid crystal display panel are provided. An indium tin oxide (ITO) layer is disposed entirely on the second metal layer, and a plurality of through-holes are disposed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. According to the present disclosure, transmittance of light is efficiently increased and performance of LCD is enhanced.

### FIELD OF THE DISCLOSURE

The present disclosure relates to the field of displaying techniques, and more particularly to an array substrate and a method for manufacturing the same and a liquid crystal display panel.

### BACKGROUND

In a typical pixel electrode layer of an array substrate, no indium tin oxide (ITO) electrode is formed in a slit portion of an ITO layer. Thus, an electric field cannot be generated between this region and an ITO substrate disposed directly above this region. Liquid crystal molecules are induced to be tilted only by adjacent ITO electrodes, resulting in low transmittance of light.

Therefore, there is a need to provide a new and improved technique to solve the above mentioned problem.

### SUMMARY OF THE DISCLOSURE

The objective of the present disclosure is to provide an array substrate and a method for manufacturing the same and a liquid crystal display panel to efficiently increase transmittance of light.

To solve the aforementioned problems, the present disclosure provides plural technical schemes as described below.

The present disclosure provides a method for manufacturing an array substrate, comprising the steps of:

providing a substrate;

depositing a first metal layer on a surface of the substrate to form a pattern of a gate electrode layer;

depositing an insulating layer on the first metal layer;

depositing an active layer on the insulating layer to form a pattern of the active layer;

depositing a second metal layer on the active layer to form a pattern of a source/drain electrode layer;

forming blanket deposition of an indium tin oxide (ITO) layer over the substrate, wherein the ITO layer is electrically connected to a plurality of drain electrodes in the second metal layer;

depositing a passivation layer on the ITO layer to form a pattern of the passivation layer;

forming a plurality of through-holes in the passivation layer by etching the passivation layer at locations corresponding to the drain electrodes; and

depositing a pixel electrode layer over the substrate to form a pattern of a plurality of pixel electrodes, wherein the pixel electrodes are electrically connected to the ITO layer via the through-holes.

Preferably, in the method for manufacturing the array substrate, the step of depositing the pixel electrode layer over the substrate to form the pattern of the plurality of pixel electrodes comprises:

forming sputter deposition of the pixel electrode layer over the substrate first, and forming the pattern of the pixel electrodes using a lithographic and etching process, such that the adjacent pixel electrodes are spaced apart.

Preferably, in the method for manufacturing the array substrate, the step of forming the through-holes in the passivation layer by etching the passivation layer at locations corresponding to the drain electrodes comprises:

etching the passivation layer at locations corresponding to the drain electrodes to form the through-holes.

Preferably, in the method for manufacturing the array substrate, the pixel electrodes in the pixel electrode layer collectively form a pattern of a fish bone with four domains.

Preferably, in the method for manufacturing the array substrate, each of a plurality of ITO electrodes in the ITO layer comprises an entire continuous plane-shaped structure.

The present disclosure further provides an array substrate, comprising:

a substrate;

a first metal layer disposed on a surface of the substrate, wherein the first metal layer includes a plurality of gate electrodes with each gate electrode used for one of a plurality of thin film transistors;

an insulating layer disposed on the first metal layer;

an active layer disposed on the insulating layer;

a second metal layer disposed on the active layer, wherein the second metal layer includes a plurality of source electrodes and a plurality of drain electrodes with each pair of source electrode and drain electrode used for one of the thin film transistors;

an indium tin oxide (ITO) layer disposed entirely on the second metal layer;

a passivation layer disposed on the ITO layer, wherein the passivation layer is used to isolate the ITO layer from a pixel electrode layer; and

the pixel electrode layer disposed on the passivation layer, wherein the pixel electrode layer includes a plurality of pixel electrodes;

wherein the ITO layer is electrically connected to the pixel electrode layer, and the ITO layer is electrically connected to the second metal layer.

Preferably, in the array substrate, a plurality of through-holes are disposed in the passivation layer at locations corresponding to the drain electrodes, such that the pixel electrodes are electrically connected to the ITO layer via the through-holes.

Preferably, in the array substrate, the adjacent pixel electrodes in the pixel electrode layer are spaced apart, and the pixel electrodes in the pixel electrode layer collectively form a pattern of a fish bone with four domains.

Preferably, in the array substrate, each of a plurality of ITO electrodes in the ITO layer comprises an entire continuous plane-shaped structure.

In addition, the present disclosure provides a liquid crystal display panel including an array substrate, a color filter substrate, and a liquid crystal cell disposed between the array substrate and the color filter substrate, wherein the array substrate comprises:

a substrate;

a first metal layer disposed on a surface of the substrate, wherein the first metal layer includes a plurality of gate electrodes with each gate electrode used for one of a plurality of thin film transistors;

an insulating layer disposed on the first metal layer;

an active layer disposed on the insulating layer;

a second metal layer disposed on the active layer, wherein the second metal layer includes a plurality of source electrodes and a plurality of drain electrodes with each pair of source electrode and drain electrode used for one of the thin film transistors;

an indium tin oxide (ITO) layer disposed entirely on the second metal layer;

a passivation layer disposed on the ITO layer, wherein the passivation layer is used to isolate the ITO layer from a pixel electrode layer; and

the pixel electrode layer disposed on the passivation layer, wherein the pixel electrode layer includes a plurality of pixel electrodes;

wherein the ITO layer is electrically connected to the pixel electrode layer, and the ITO layer is electrically connected to the second metal layer.

Preferably, in the liquid crystal display panel, a plurality of through-holes are disposed in the passivation layer at locations corresponding to the drain electrodes, such that the pixel electrodes are electrically connected to the ITO layer via the through-holes.

Preferably, in the liquid crystal display panel, the adjacent pixel electrodes in the pixel electrode layer are spaced apart, and the pixel electrodes in the pixel electrode layer collectively form a pattern of a fish bone with four domains.

Preferably, in the liquid crystal display panel, each of a plurality of ITO electrodes in the ITO layer comprises an entire continuous plane-shaped structure.

Compared to conventional techniques, an indium tin oxide (ITO) layer is blanket deposited on the second metal layer, and a plurality of through-holes are formed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. In other words, the present disclosures proposes forming an additional ITO layer under the pixel electrodes in the conventional polymer stabilized vertical alignment (PSVA) pixels of LCD to form new PSVA pixels. Since the ITO layer is blanket deposited, an electric field can be generated between the slit portion and the ITO electrodes disposed on the upper substrate. Therefore, the liquid crystal molecules therebetween are able to be tilted to transmit light. Thus, according to the present disclosure, transmittance of light is efficiently increased and performance of LCD is enhanced.

Preferred embodiments are provided below to more easily understand the above technical content of the subject invention with reference to the accompanying drawings.

### BRIEF DESCRIPTION OF THE DRAWINGS

FIG. 1 shows a flow chart of a method for manufacturing an array substrate according to an embodiment of the present disclosure.

FIG. 2 is a schematic diagram showing a structure of an array substrate according to an embodiment of the present disclosure.

FIG. 3 is a schematic diagram showing a structure of the pixel electrodes in a pixel electrode layer of an embodiment of the present disclosure.

FIG. 4 is a schematic diagram showing a structure of one of the ITO electrodes in an ITO layer of an embodiment of the present disclosure.

### DETAILED DESCRIPTION

The term “embodiment” used in this description refers to an example, a demonstration, or an illustration. In addition, the two indefinite articles “a” and “an” used in this description and claims are generally understood as “one or more” unless a specific single form is pointed out or is determined in the context.

According to the present disclosure, an indium tin oxide (ITO) layer is blanket deposited on the second metal layer, and a plurality of through-holes are formed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. In other words, the present disclosures proposes forming an additional ITO layer under the pixel electrodes in the conventional polymer stabilized vertical alignment (PSVA) pixels of LCD to form new PSVA pixels. Since the ITO layer is blanket deposited, an electric field can be generated between the slit portion and the ITO electrodes disposed on the upper substrate. Therefore, the liquid crystal molecules therebetween are able to be tilted to transmit light. Thus, according to the present disclosure, transmittance of light is efficiently increased and LCD performance is enhanced.

### Embodiment 1

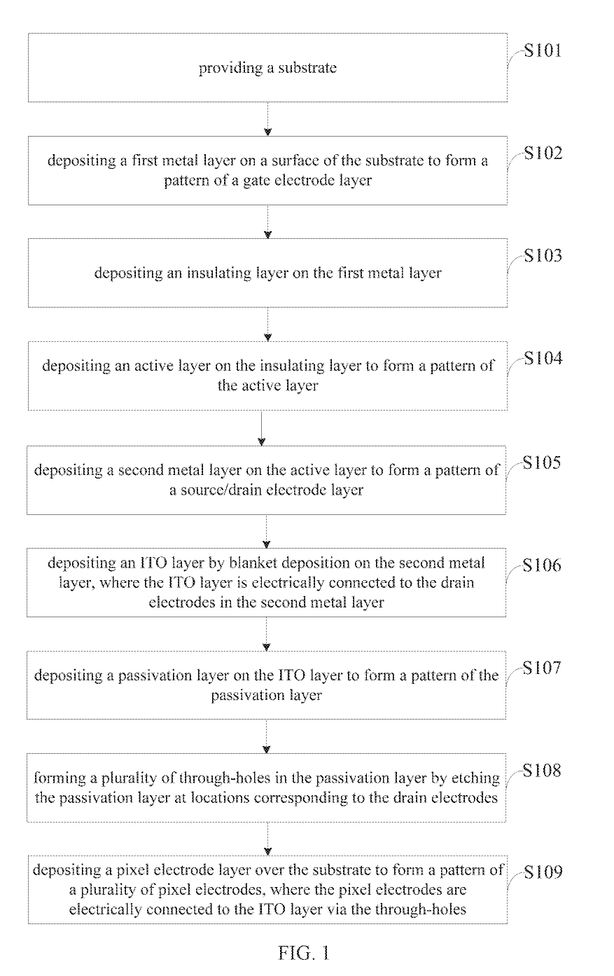

Please refer to FIG. 1 which shows a flow chart of a method for manufacturing an array substrate according to an embodiment of the present disclosure. The method for manufacturing an array substrate according to an embodiment of the present disclosure includes the following steps.

In step S101, a substrate is provided.

According to the embodiment of the present disclosure, the substrate is a glass substrate.

In step S102, a first metal layer is deposited on a surface of the substrate to form a pattern of a gate electrode layer.

According to the embodiment of the present disclosure, the first metal layer is deposited on a surface of the substrate first, and a lithographic and etching process is used to pattern the first metal layer, where the generated pattern of the first metal layer includes a plurality of gate electrodes with each gate electrode used for one of a plurality of thin film transistors.

In step S103, an insulating layer is deposited on the first metal layer.

In step S104, an active layer is deposited on the insulating layer to form a pattern of the active layer.

In step S105, a second metal layer is deposited on the active layer to form a pattern of a source/drain electrode layer.

According to the embodiment of the present disclosure, the second metal layer is deposited over the substrate by blanket deposition first, and a lithographic and etching process is used to pattern the second metal layer, where the generated pattern of the second metal layer includes a plurality of source electrodes and a plurality of drain electrodes with each pair of source electrode and drain electrode used for one of the thin film transistors.

In step S106, an ITO layer is blanket deposited on the second metal layer, where the ITO layer is electrically connected to the drain electrodes in the second metal layer.

As a preferred embodiment of the present disclosure, each of a plurality of ITO electrodes in the ITO layer comprises an entire continuous plane-shaped structure.

In step S107, a passivation layer is deposited on the ITO layer to form a pattern of the passivation layer.

In step S108, a plurality of through-holes are formed in the passivation layer by etching the passivation layer at locations corresponding to the drain electrodes.

According to the embodiment of the present disclosure, the passivation layer at locations corresponding to the drain electrodes is etched to form the through-holes.

In step S109, a pixel electrode layer is deposited over the substrate to form a pattern of a plurality of pixel electrodes, where the pixel electrodes are electrically connected to the ITO layer via the through-holes.

According to the embodiment of the present disclosure, sputter deposition of the pixel electrode layer over the substrate is performed first, and a lithographic and etching process is used to form the pattern of the pixel electrodes, such that the adjacent pixel electrodes are spaced apart.

As a preferred embodiment of the present disclosure, the pixel electrodes in the pixel electrode layer collectively form a pattern of a fish bone with four domains.

It is understood from the above description that the Embodiment 1 of the present disclosure provides a method for manufacturing an array substrate. An ITO layer is blanket deposited on the second metal layer, and a plurality of through-holes are formed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. In other words, the present disclosures proposes additionally forming an ITO layer under the pixel electrodes in the conventional polymer stabilized vertical alignment (PSVA) pixels of LCD to form new PSVA pixels. Since the ITO layer is blanket deposited, an electric field can be generated between the slit portion and the ITO electrodes disposed on the upper substrate. Therefore, the liquid crystal molecules therebetween are able to be tilted to transmit light. Thus, according to the present disclosure, transmittance of light is efficiently increased and performance of LCD is enhanced.

### Embodiment 2

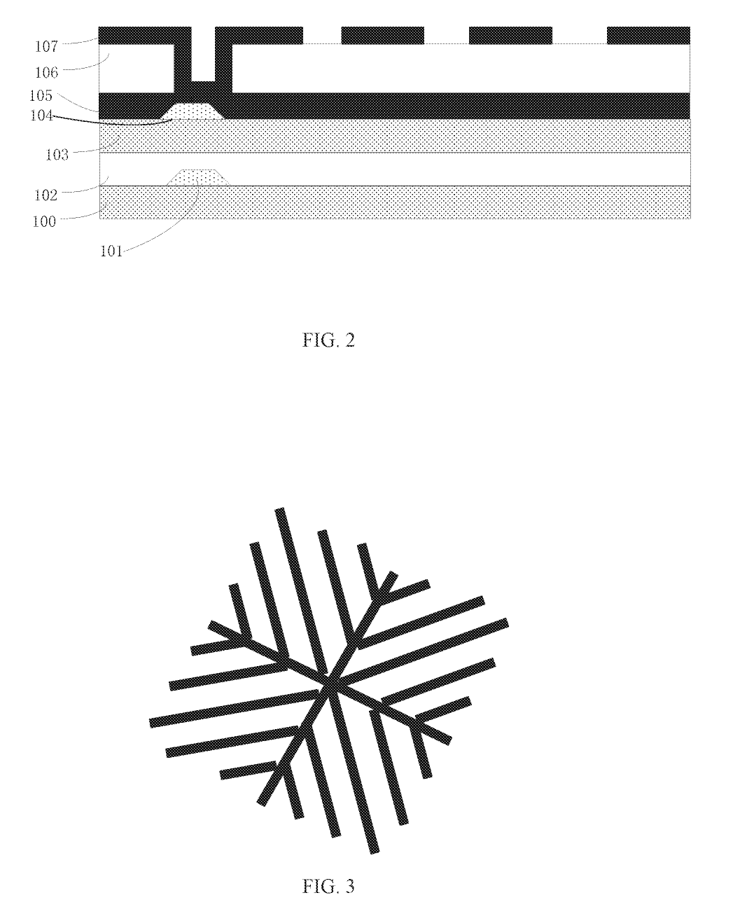

Please refer to FIG. 2 which is a schematic diagram showing a structure of an array substrate according to an embodiment of the present disclosure. For ease of understanding, this embodiment only indicates portions that are relevant to the embodiment of the present disclosure.

According to the embodiment of the present disclosure, the array substrate includes: a substrate 100; a first metal layer 101; an insulating layer 102; an active layer 103; a second metal layer 104; an ITO layer 105; a passivation 106; and a pixel electrode layer 107. The first metal layer 101 is disposed on a surface of the substrate 100. The first metal layer 101 includes a plurality of gate electrodes with each gate electrode used for one of a plurality of thin film transistors. The insulating layer 102 is disposed on the first metal layer 101. The active layer 103 is disposed on the insulating layer 102. The second metal layer 104 is disposed on the active layer 103, where the second metal layer 104 includes a plurality of source electrodes and a plurality of drain electrodes with each pair of source electrode and drain electrode used for one of the thin film transistors. The ITO layer 105 is disposed entirely on the second metal layer 104. The passivation layer 106 is disposed on the ITO layer 105, where the passivation layer 106 is used to isolate the ITO layer 105 from the pixel electrode layer 107. The pixel electrode layer 107 is disposed on the passivation layer 106, where the pixel electrode layer 107 includes a plurality of pixel electrodes;

The ITO layer 105 is electrically connected to the pixel electrode layer 107. Additionally, the ITO layer 105 is electrically connected to the second metal layer 104 with both having the same electric potential.

Preferably, a plurality of through-holes are disposed in the passivation layer 106 at locations corresponding to the drain electrodes, such that the pixel electrodes are electrically connected to the ITO layer via the through-holes.

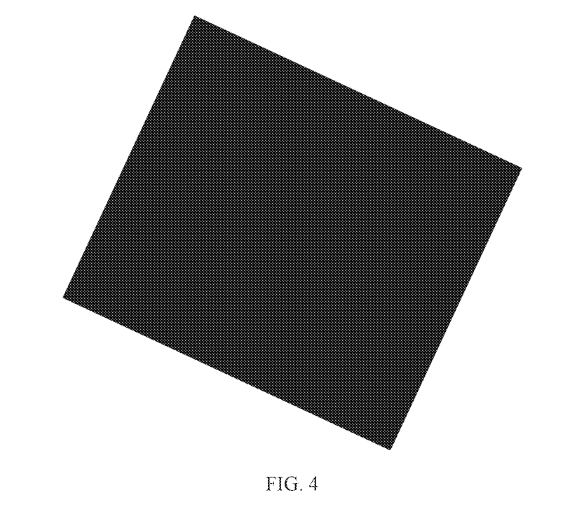

As shown FIG. 3, in a preferred embodiment of the present disclosure, the adjacent pixel electrodes in the pixel electrode layer are spaced apart, and the pixel electrodes in the pixel electrode layer collectively form a pattern of a fish bone with four domains.

As shown FIG. 4, in a preferred embodiment of the present disclosure, each of a plurality of ITO electrodes in the ITO layer comprises an entire continuous plane-shaped structure.

According to the embodiment of the present disclosure, the first metal layer 101 is deposited on a surface of the substrate 100 first, and a lithographic and etching process is used to pattern the first metal layer 101, where the generated pattern of the first metal layer 101 includes a plurality of gate electrodes with each gate electrode used for one of a plurality of thin film transistors.

According to the embodiment of the present disclosure, the second metal layer 104 is deposited over the substrate by blanket deposition first, and a lithographic and etching process is used to pattern the second metal layer 104, where the generated pattern of the second metal layer 104 includes a plurality of source electrodes and a plurality of drain electrodes with each pair of source electrode and drain electrode used for one of the thin film transistors.

According to the embodiment of the present disclosure, sputter deposition of the pixel electrode layer 107 over the substrate is performed first, and a lithographic and etching process is used to pattern the pixel electrode layer 107, where the generated pattern of the pixel electrode layer 107 includes a plurality of pixel electrodes.

According to the embodiment of the present disclosure, the pixel electrode layer 107 is made of a material such as indium tin oxide (ITO) or indium zinc oxide (IZO). The insulating layer 102 can be made of G-SiNx. It should be noted, however, that the pixel electrode layer and the insulating layer are made of materials that are not limited to the above mentioned ones. All the changes, equivalent alternatives, and modifications made thereto based on spirit and principle of the present disclosure are intended to be covered by the scope of the subject invention.

It is understood from the above description that the Embodiment 2 of the present disclosure provides an array substrate. An ITO layer is disposed entirely on the second metal layer, and a plurality of through-holes are formed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. In other words, the present disclosures proposes additionally disposing an ITO layer under the pixel electrodes in the conventional polymer stabilized vertical alignment (PSVA) pixels of LCD to form new PSVA pixels. Since the ITO layer is blanket deposited, an electric field can be generated between the slit portion and the ITO electrodes disposed on the upper substrate. Therefore, the liquid crystal molecules therebetween are able to be tilted to transmit light. Thus, according to the present disclosure, transmittance of light is efficiently increased and performance of LCD is enhanced.

### Embodiment 3

The present disclosure further provides a liquid crystal display panel. For ease of understanding, this embodiment only indicates portions that are relevant to the embodiment of the present disclosure. According to the embodiment of the present disclosure, the liquid crystal display panel includes an array substrate, a color filter substrate, and a liquid crystal cell disposed between the array substrate and the color filter substrate.

The array substrate includes: a substrate 100; a first metal layer 101; an insulating layer 102; an active layer 103; a second metal layer 104; an ITO layer 105; a passivation 106; and a pixel electrode layer 107. The first metal layer 101 is disposed on a surface of the substrate 100. The first metal layer 101 includes a plurality of gate electrodes with each gate electrode used for one of a plurality of thin film transistors. The insulating layer 102 is disposed on the first metal layer 101. The active layer 103 is disposed on the insulating layer 102. The second metal layer 104 is disposed on the active layer 103, where the second metal layer 104 includes a plurality of source electrodes and a plurality of drain electrodes with each pair of source electrode and drain electrode used for one of the thin film transistors. The ITO layer 105 is disposed entirely on the second metal layer 104. The passivation layer 106 is disposed on the ITO layer 105, where the passivation layer 106 is used to isolate the ITO layer 105 from the pixel electrode layer 107. The pixel electrode layer 107 is disposed on the passivation layer 106, where the pixel electrode layer 107 includes a plurality of pixel electrodes;

The ITO layer 105 is electrically connected to the pixel electrode layer 107. Additionally, the ITO layer 105 is electrically connected to the second metal layer 104.

Preferably, a plurality of through-holes are disposed in the passivation layer 106 at locations corresponding to the drain electrodes, such that the pixel electrodes are electrically connected to the ITO layer via the through-holes.

Preferably, the adjacent pixel electrodes in the pixel electrode layer are spaced apart, and the pixel electrodes in the pixel electrode layer collectively form a pattern of a fish bone with four domains.

Preferably, each of a plurality of ITO electrodes in the ITO layer comprises an entire continuous plane-shaped structure.

Therefore, according to the present disclosure, an ITO layer is disposed entirely on the second metal layer, and a plurality of through-holes are formed in the passivation layer at locations corresponding to the drain electrodes in the second metal layer, so that the pixel electrodes in the pixel electrode layer are electrically connected to the ITO layer via the through-holes, and the ITO layer is electrically connected to the second metal layer. In other words, the present disclosures proposes additionally disposing an ITO layer under the pixel electrodes in the conventional polymer stabilized vertical alignment (PSVA) pixels of LCD to form new PSVA pixels. Since the ITO layer is blanket deposited, an electric field can be generated between the slit portion and the ITO electrodes disposed on the upper substrate. Therefore, the liquid crystal molecules therebetween are able to be tilted to transmit light. Thus, according to the present disclosure, transmittance of light is efficiently increased and performance of LCD is enhanced.

In summary, while the present disclosure has been described with one or more embodiments, it is easy for any person having ordinary skill in the art to make any equivalent changes and modifications thereto in view of the description and drawings of the present specification. The present disclosure includes such changes and modifications, and the scope of the subject invention is determined by the claims. In particular, regarding various functions executed by the above mentioned components, the terms described and used to represent the above mentioned components are intended to equivalently correspond to any components (e.g., executing equivalent functions) that execute the functions of the described components, unless indicated to the contrary, even if such any components have structures that are different from the disclosed structures of the above mentioned components in the embodiments of the present disclosure. In addition, though only one feature is provided in the present disclosure with respect to others, the feature can be combined with one or more of other features that are beneficial for certain applications. Moreover, the terms “include”, “have”, or “contain” and its variants used in the specification or claim are intended to have a similar meaning to “comprise”.

In summary, while the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A method for manufacturing an array substrate, comprising the steps of:
providing a substrate;
depositing a first metal layer on a surface of the substrate to form a pattern of a gate electrode layer;
depositing an insulating layer on the first metal layer;
depositing an active layer on the insulating layer to form a pattern of the active layer;
depositing a second metal layer on the active layer to form a pattern of a source/drain electrode layer;
blanket depositing an indium tin oxide (ITO) layer over the substrate, wherein the ITO layer is electrically connected to a plurality of drain electrodes in the second metal layer;
depositing a passivation layer on the ITO layer to form a pattern of the passivation layer;
forming a plurality of through-holes in the passivation layer by etching the passivation layer at locations corresponding to the drain electrodes; and
depositing a pixel electrode layer over the substrate to form a pattern of a plurality of pixel electrodes, wherein the pixel electrodes are electrically connected to the ITO layer via the through-holes.

2. The method for manufacturing the array substrate according to claim 1, wherein the step of depositing the pixel electrode layer over the substrate to form the pattern of the plurality of pixel electrodes comprises:
forming sputter deposition of the pixel electrode layer over the substrate first, and forming the pattern of the pixel electrodes using a lithographic and etching process, such that the adjacent pixel electrodes are spaced apart.

3. The method for manufacturing the array substrate according to claim 1, wherein the step of forming the through-holes in the passivation layer by etching the passivation layer at locations corresponding to the drain electrodes comprises:
etching the passivation layer at locations corresponding to the drain electrodes to form the through-holes.

4. The method for manufacturing the array substrate according to claim 1, wherein the pixel electrodes in the pixel electrode layer collectively form a pattern of a fish bone with four domains.

5. The method for manufacturing the array substrate according to claim 1, wherein each of a plurality of ITO electrodes in the ITO layer comprises an entire continuous plane-shaped structure.

6. An array substrate, comprising:
a substrate;
a first metal layer disposed on a surface of the substrate, wherein the first metal layer includes a plurality of gate electrodes with each gate electrode used for one of a plurality of thin film transistors;
an insulating layer disposed on the first metal layer;
an active layer disposed on the insulating layer;
a second metal layer disposed on the active layer, wherein the second metal layer includes a plurality of source electrodes and a plurality of drain electrodes with each pair of source electrode and drain electrode used for one of the thin film transistors;
an indium tin oxide (ITO) layer disposed entirely on the second metal layer;
a passivation layer disposed on the ITO layer, wherein the passivation layer is used to isolate the ITO layer from a pixel electrode layer; and
the pixel electrode layer disposed on the passivation layer, wherein the pixel electrode layer includes a plurality of pixel electrodes;
wherein the ITO layer is electrically connected to the pixel electrode layer, and the ITO layer is electrically connected to the second metal layer.

7. The array substrate according to claim 6, wherein a plurality of through-holes are disposed in the passivation layer at locations corresponding to the drain electrodes, such that the pixel electrodes are electrically connected to the ITO layer via the through-holes.

8. The array substrate according to claim 6, wherein the adjacent pixel electrodes in the pixel electrode layer are spaced apart, and the pixel electrodes in the pixel electrode layer collectively form a pattern of a fish bone with four domains.

9. The array substrate according to claim 6, wherein each of a plurality of ITO electrodes in the ITO layer comprises an entire continuous plane-shaped structure.

10. A liquid crystal display panel including an array substrate, a color filter substrate, and a liquid crystal cell disposed between the array substrate and the color filter substrate, wherein the array substrate comprises:
a substrate;
a first metal layer disposed on a surface of the substrate, wherein the first metal layer includes a plurality of gate electrodes with each gate electrode used for one of a plurality of thin film transistors;
an insulating layer disposed on the first metal layer;
an active layer disposed on the insulating layer;
a second metal layer disposed on the active layer, wherein the second metal layer includes a plurality of source electrodes and a plurality of drain electrodes with each pair of source electrode and drain electrode used for one of the thin film transistors;
an indium tin oxide (ITO) layer disposed entirely on the second metal layer;
a passivation layer disposed on the ITO layer, wherein the passivation layer is used to isolate the ITO layer from a pixel electrode layer; and
the pixel electrode layer disposed on the passivation layer, wherein the pixel electrode layer includes a plurality of pixel electrodes;
wherein the ITO layer is electrically connected to the pixel electrode layer, and the ITO layer is electrically connected to the second metal layer.

11. The liquid crystal display panel according to claim 10, wherein a plurality of through-holes are disposed in the passivation layer at locations corresponding to the drain electrodes, such that the pixel electrodes are electrically connected to the ITO layer via the through-holes.

12. The liquid crystal display panel according to claim 10, wherein the adjacent pixel electrodes in the pixel electrode layer are spaced apart, and the pixel electrodes in the pixel electrode layer collectively form a pattern of a fish bone with four domains.

13. The liquid crystal display panel according to claim 10, wherein each of a plurality of ITO electrodes in the ITO layer comprises an entire continuous plane-shaped structure.
